(19) United States
(12) Patent Application Publication
(10) Pub. No.: US 2016/0168698 A1
(43) Pub. Date: Jun. 16, 2016

(54) Systems, Devices, and/or Methods for Deposition of Metallic and Ceramic Coatings

(71) Applicant: Directed Vapor Technologies International, Inc., Charlottesville, VA (US)

(72) Inventor: Derek Hass, Charlottesville, VA (US)

(73) Assignee: Directed Vapor Technologies International, Inc., Charlottesville, VA (US)

(21) Appl. No.: 14/969,083

(22) Filed: Dec. 15, 2015

Related U.S. Application Data
(60) Provisional application No. 62/091,794, filed on Dec. 15, 2014.

(51) Int. Cl. C23C 16/44

(52) U.S. Cl. CPC C23C 16/44

(57) ABSTRACT

Certain exemplary embodiments can provide a method, which can comprise depositing a substantially uniform coating on a substrate. The coating is deposited via a coating material stream that emanates from one or more vapor sources. The coating material stream is directed toward the substrate via a carrier gas in a chamber under vacuum.

### CROSS-REFERENCES TO RELATED APPLICATIONS

This application claims priority to, and incorporates by reference herein in its entirety, pending U.S. Provisional Patent Application Ser. No. 62/091,794, filed Dec. 15, 2014. This application is related to issued patent U.S. Pat. No. 7,014,889 (having an issue date of Mar. 21, 2006), which is incorporated by reference in its entirety.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1 is a block diagram of an exemplary embodiment of a system 1000;

FIG. 2 is a block diagram of an exemplary embodiment of a system 2000;

FIG. 3 is a block diagram of an exemplary embodiment of a system 3000;

FIG. 4 is a block diagram of an exemplary embodiment of a system 4000; and

FIG. 5 is a flowchart of an exemplary embodiment of a method 5000.

### DETAILED DESCRIPTION

Certain exemplary embodiments can provide a method, which can comprise depositing a substantially uniform coating on a substrate. The coating is deposited via a coating material stream that emanates from one or more vapor sources. The coating material stream is directed toward the substrate via a carrier gas in a chamber under vacuum.

Certain repair facilities use vapor deposition processes to apply corrosion resistant coatings (such as pure aluminum) onto a variety of substrates (e.g., landing gear and fasteners). Certain approaches use high vacuum environments for substantially line-of-sight (“LOS”) coating application. Vapor deposition processes are also used to apply thermal barrier coatings (TBCs) onto substrates such as hot section gas turbine engine components. Electron beam physical vapor deposition (EB-PVD) approaches that can be employed for the application of TBCs use very large, expensive coating equipment that is not affordable to install on-site at repair depots and, as a result, is often performed at off-site locations. Similar vapor deposition processes may also be used for new coating applications which relate to the incorporation of wear coatings onto the internal regions of titanium based landing gear. Certain processes do not apply coatings onto non-line-of-sight (“NLOS”) regions of substrates.

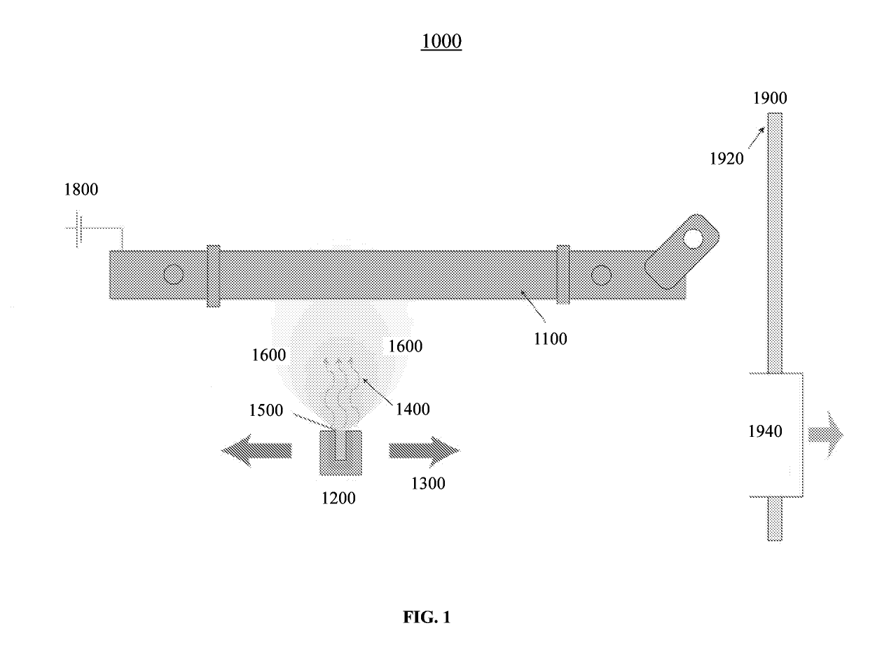

FIG. 1 is a block diagram of an exemplary embodiment of a system 1000, which comprises a component 1100 (e.g., a steel landing gear component), a heated boat 1200 (e.g., a movable resistively heated boat constructed to hold aluminum), a wire feed 1500 (e.g., an aluminum wire feed), a connection to a voltage source 1800 (e.g., a voltage source of between approximately −500 volts and 1500 volts), and a chamber wall 1900. Radiant heat 1300 and vapor radiant heat 1400 flow from heated boat 1200 when boat 1200 is heated. Vapor 1600 emanates from heated boat 1200 when boat 1200 is heated sufficiently to cause wire feed 1500 to evaporate and/or sublimate. A size and complexity of component 1100 dictates that component 1100 remain substantially stationary (i.e., non-rotated) during deposition. Component 1100 should not be overheated such that component 1100 substantially retains certain mechanical properties. In operating systems, condensation 1920 can form. Condensation 1920 can comprise water and/or materials comprised by wire feed 1500. Passages 1940 can route a flow of condensation 1920 to diffusion and/or mechanical pumps (not illustrated). System 1000 can be utilized for an ion vapor deposition approach for the application of aluminum corrosion protection coatings onto substrates such as aircraft components. System 1000 can be used in a method comprising one or more of the following processing steps:
insert part;
apply a vacuum (e.g., approximately 9.0×10-5 torr), which can take several hours;
backfill argon (e.g., to approximately 1×10-2 torr);
apply negative potential to part for glow discharge cleaning;
coat first side of component ;
cool and vent component ;
rotate component;
repeat the first four listed processing steps;
coat the second side of the component;
cool and vent component;
post processing (e.g., burnishing); and/or
apply a chromate conversion coat.

To combat corrosion, surfaces can be coated with cadmium coatings (e.g., applied using an electroplating process) applied to provide sacrificial galvanic protection against corrosion. Due to the hazardous nature of cadmium, many applications have transitioned to the use of aluminum coatings to provide corrosion protection. The aluminum coatings can be applied using vapor deposition process called ion vapor deposition (IVD). In such an approach, thermally evaporated aluminum is created using resistive heating in a high vacuum environment, see, e.g., FIG. 1. The vapor is then condensed onto a substrate having a large negative applied potential to create a semi-dense coating. The result is a substantially non-toxic processing approach for the creation of corrosion protection coatings. However, the IVD aluminum coating process can have a number of limitations that restricts its utilization, lowers its efficiency, and increases usage costs. These are driven by the use of the relatively high vacuum environment which limits coating application onto substantially line-of-sight regions of the substrate, leads to relatively long chamber pump down times and promotes substrate overheating. The performance of IVD-aluminum coatings can also be limited by the semi-dense microstructure which results in the need for post-coating densification treatments. In addition this process is not very amenable to the deposition of Al alloy coatings.

The use of a gas jet assisted vapor deposition process, Directed Vapor Deposition (DVD), for the application of aluminum-based corrosion resistant coatings is a solution that can enable achievement of a non-toxic, non-line-of-sight, and dense coating. This process can utilize an inert gas jet in a soft vacuum (reduced chamber pump down requirements) environment to direct an evaporated aluminum or aluminum alloy flux onto line-of-sight and non-line-of-sight regions of substrates. The approach retains the certain non-toxic attributes of the IVD-aluminum process, while significantly improving efficiency as compared to exemplary IVD-aluminum processes, as well as facilitating the coating of substrates with complex shapes and improving the corrosion protection of the resulting coatings.

In addition to providing significant improvements over the current IVD-aluminum approach, the DVD process can also allow affordable coaters to be designed to support other current and future depot needs. This is due to the non-line-of-sight (NLOS) attributes of the DVD process that provide coating efficiency based on NLOS capabilities that enable substantially three-dimensional (“3D”) utilization of the vapor flux and the capability to coat complex substrates having shielded or hidden regions. DVD has been demonstrated to be effective at applying corrosion, wear, and thermal barrier coatings onto test coupons and complexly shaped substrates. Processing of large substrates is further enabled by the improvements disclosed herein, as part translation becomes more challenging with greater substrate dimensions and/or mass.

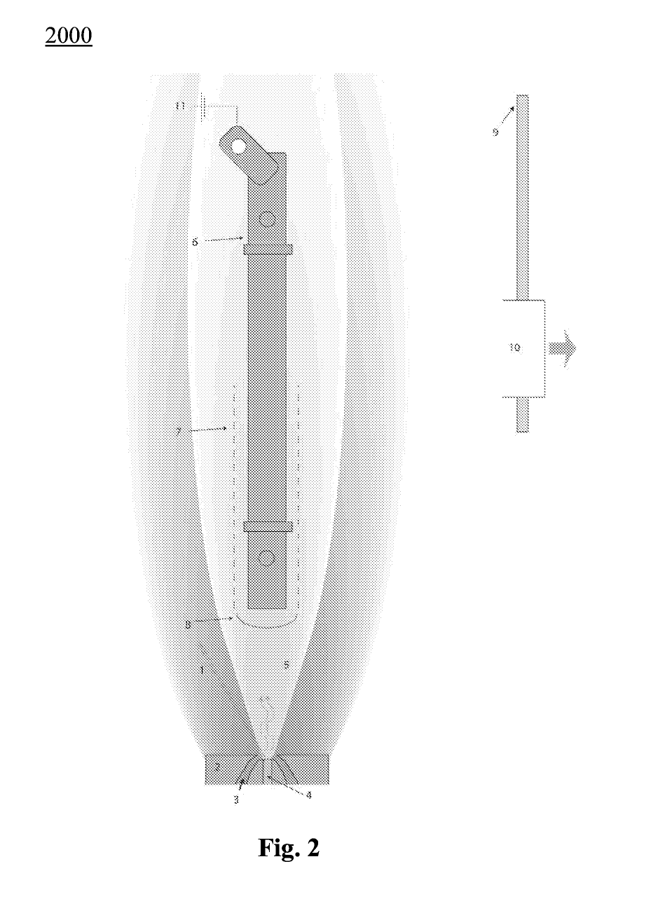

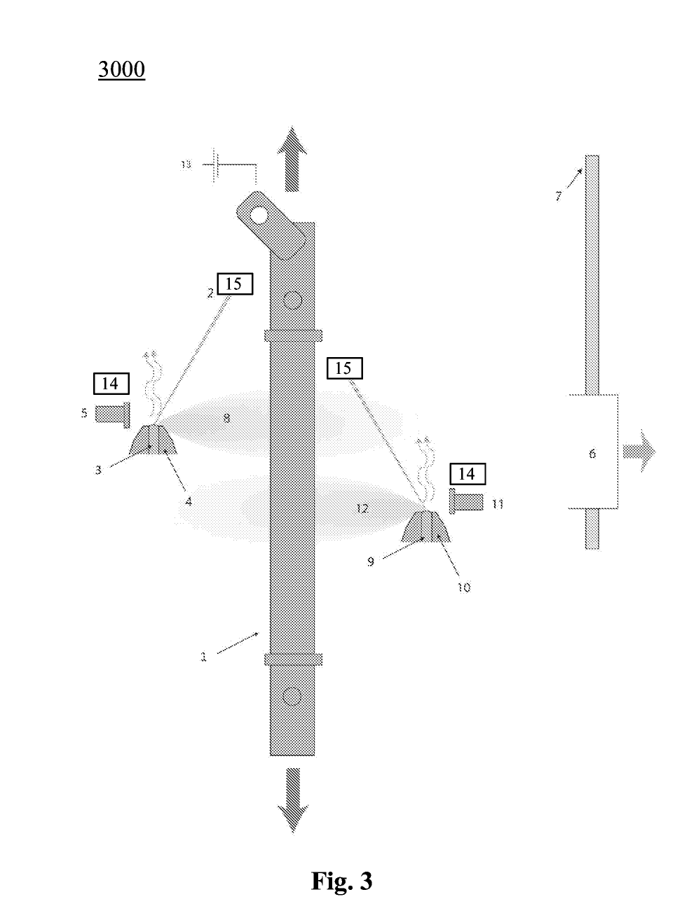

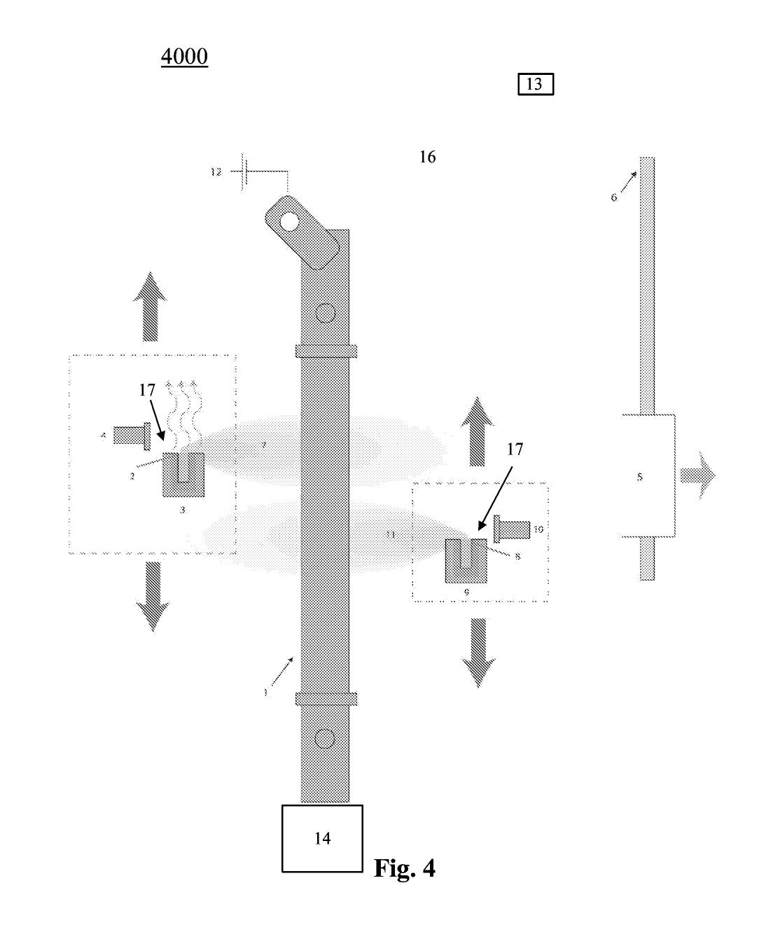

The unique processing environment created by the Directed Vapor Deposition approach, enable coating equipment, as shown in FIG. 2, FIG. 3, and FIG. 4, that have:
very short pump-down times (due to the soft vacuum environment);
can coat large substrates in a single processing sequence (due to the ability to coat substantially in a non-line-of-sight manner while directing the vapor onto the substrate from multiple directions);
have short coating cycles (the ability to focus the vapor onto the substrate and not the walls of the coating chamber allows for a high utilization of the evaporation flux and therefore enhanced deposition rates);
apply coating onto the internal regions of substrates (due to the NLOS capability);
limit overheating of substrates (due to convective cooling mechanisms that can be applied when using gas jets in a soft vacuum environment of between approximately 1 Pascal to approximately 100 Pascals);
shield the substrate from impurities (such as water vapor, oxygen) on the walls of the coating chamber that can affect coating durability;
can apply aluminum alloy coatings for enhanced corrosion performance; and/or
can apply a variety of other metal and ceramic materials to impart altered surface properties to a substrate.

FIG. 2 is a block diagram of an exemplary embodiment of a system 2000, which uses substantially non-line-of-sight attributes of a process to coat a substrate. System 2000 can be utilized in a directed vapor deposition process used to deposit aluminum, aluminum alloy, cadmium, and/or wear resistant coatings onto substrates which can be aircraft components. The coating process takes place in vacuum environment enclosed by the chamber walls 9 with passages 10 to mechanical pumps constructed to remove condensate from system 2000. A high-frequency scanning electron beam 1 impinges on evaporant material 4 to create a vapor plume 5. The gas jet 3, formed by the nozzle 2, is used to direct atoms comprised by vapor plume 5 towards a substrate 6, which deposit by laterally scattering onto the external and internal regions of the substrate. Solid or porous masks capable of producing radiant heat 8 are placed at regions of the substrate which receive significant line-of-sight deposition to enhance the coating uniformity in non-line-of-sight regions 7. Hollow cathode plasma activation (e.g., via a plasma source such as plasma source 14 of FIG. 3) of the vapor flux, in conjunction with biasing 11 of substrate 6, may also be used to enhance coating density.

FIG. 3 is a block diagram of an exemplary embodiment of a system 3000, which translates the substrate within the vapor plume created by a plurality of stationary nozzles. System 3000 can be used in a directed vapor deposition process used to deposit aluminum, aluminum alloy, cadmium, and wear resistant coatings onto substrates which are aircraft components. The coating process takes place in vacuum environment enclosed by the chamber walls 7 with passages 6 to mechanical pumps, which mechanical pumps are constructed to remove condensation from system 3000. A high-frequency scanning electron beam 2 impinges on a plurality of evaporant materials 3 and 9, which can be continuously fed from a plurality of crucibles 4 and 10, to create a plurality of vapor plumes 8 and 12. A plurality of gas jets 5 and 11 are used to direct atoms comprised by vapor plumes 8 and 12, which plumes have been created using electron beam evaporation or resistive heating, towards the substrate 1. Atoms comprised by vapor plumes 8 and 12 then deposit across the surface of substrate 1. Translation of substrate 1 is used to promote coating uniformity. Substrate 1 may be held in a vertical or horizontal arrangement. Hollow cathode plasma activation 14 of the vapor flux in conjunction with biasing 13 of the substrate may also be used to enhance coating density.

FIG. 4 is a block diagram of an exemplary embodiment of a system 4000, which illustrates an embodiment in which a plurality of nozzles is moved around a substantially stationary substrate. System 4000 can be used in a directed vapor deposition process that deposits coatings such as aluminum, aluminum alloy, cadmium, and wear resistant coatings onto substrates, which can be aircraft components. The coating process takes place in vacuum environment enclosed by the chamber walls 6 with passages 5 to mechanical pumps, which mechanical pumps are constructed to remove condensation from system 4000. A plurality of resistive heated crucibles 3 and 9 are used to melt evaporant materials 2 and 8, which can be in wire form. Crucibles 3 and 9 substantially contain molten material until the molten material evaporates. A plurality of gas jets 4 and 10 are used to direct vapor flux 7 and 11, which vapor flux 7 and 11 have been created using heating (e.g., resistive heating), towards substrate 1. Atoms comprised by vapor flux 7 and 11 can then deposit across the surface of substrate 1. Translation of the vapor sources is used to promote coating uniformity. Substrate 1 may be held in a vertical or horizontal arrangement. Hollow cathode plasma activation (e.g., via a plasma source such as plasma source 14 of FIG. 3) of the vapor flux in conjunction with biasing 12 of substrate 1 may also be used to enhance coating density.

System 4000 can comprise:
substrate 1;
a plasma source (e.g., plasma source 14 of FIG. 3) that ionizes at least a portion of the coating material or carrier gas;
a pre-heater 14 that transfers heat energy to substrate 1;
an electron beam source (e.g., electron beam source 15 of FIG. 3) that supplies an electron beam (e.g., electron beam 2 of FIG. 3) that evaporates or sublimates the coating material;
a vacuum pump 13 that creates a vacuum in chamber 16 (e.g., a coating chamber);
a plurality of crucibles 3 and 9 (e.g., metal crucibles) from which wires (e.g., wire feed 1500 of FIG. 1) are evaporated to generate a coating material stream (i.e., vapor flux 7 and 11);
the coating material stream emanates from one or more vapor sources (i.e., heated crucibles 3 and 9), wherein the coating material stream is directed toward substrate 1 via a carrier gas 17 in chamber 16 under vacuum. Carrier gas 17 substantially surrounding the coating material stream as substrate 1 is exposed to a coating material comprised by the coating material stream; wherein:
   the coating material stream moves relative to substrate 1 as the coating material is deposited on substrate 1; and
   the coating material is deposited as a substantially uniform layer on substrate 1 via non-line of sight coating of at least a portion of substrate 1;

In certain exemplary embodiments:
a bias (e.g., via biasing 12) is applied to substrate 1 to enhance a coating density of the coating material on substrate 1;
carrier gas 17 is directed in chamber 16 via a gas jet nozzle (e.g., nozzle 2 of FIG. 2), which can comprise at least one of an angular channel and a non-angular channel;
carrier gas 18 is directed in the chamber via a gas jet nozzle (e.g., nozzle 2 of FIG. 2) defined by a shape selected from the group consisting of: ring-shaped, elliptical-shaped, elongated elliptical-shaped, cross-hatched-shaped, segmented ring-shaped, segmented elliptical-shaped, and segmented elongated elliptical-shaped;
the coating material comprises cadmium;
the coating material comprises aluminum;
the coating material comprises an aluminum alloy;
substrate 1 is an aircraft component;
substrate 1 is an aircraft landing gear, actuator, or connector component; and/or
an internal portion of substrate 1 is coated via non line of sight coating.

### EXAMPLES

### Example 1

DVD Aluminum Coatings for External Regions: a next generation vapor deposition coater based on DVD technology can be used to apply aluminum coating onto substrates, which can be aircraft components, which substrates might have been subjected IVD aluminum coatings in the past for corrosion protection. DVD technology can be quicker and more efficient manner and can utilize easier to use equipment that is less expensive to operate and maintain.

### Example 2

DVD Aluminum Alloy Coatings for External Regions: a next generation vapor deposition coater based on DVD technology can be used to apply aluminum alloy coatings onto substrates, which can be aircraft components, which substrates might have had IVD aluminum coatings applied for corrosion protection. DVD technology can apply coatings that provide enhanced corrosion protection.

### Example 3

DVD Aluminum/Aluminum Alloy Coatings for NLOS Internal

Regions: a next generation vapor deposition coater based on DVD technology can be used to apply aluminum and aluminum alloy coatings onto NLOS regions of substrates, which can be aircraft components, which substrates had cadmium coatings for corrosion protection previously applied. Such DVD technology can aid in the elimination of cadmium from use to reduce hazardous waste removal costs associated with cadmium usage.

### Example 4

DVD Wear Coatings for NLOS Internal Regions: a next generation vapor deposition coater based on DVD technology can be used to apply wear resistant coatings onto NLOS regions of substrates, which can be aircraft components.

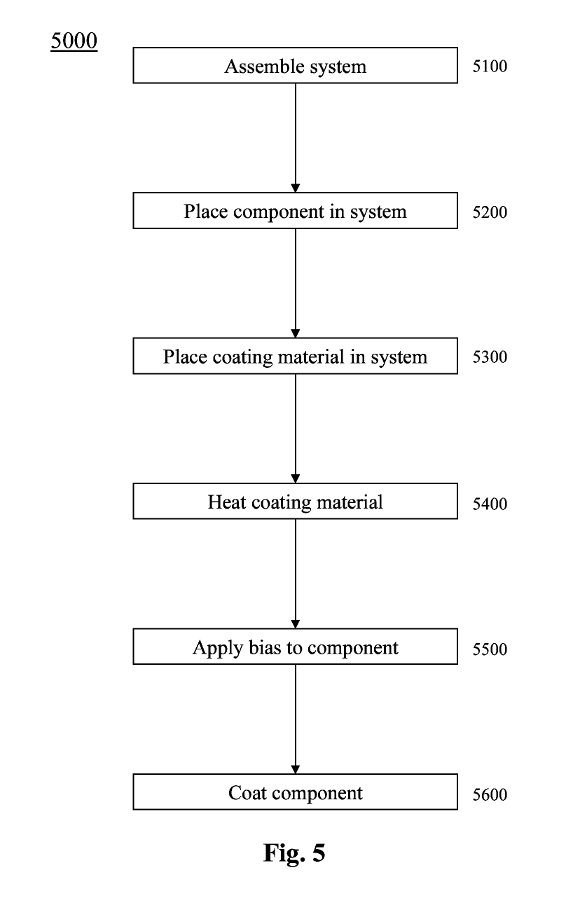

FIG. 5 is a flowchart of an exemplary embodiment of a method 5000. At activity 5100, a system can be assembled. The system can comprise a coating material, a crucible, a gas jet nozzle, a substrate, an electron beam, a plasma source, a component handling system, a gas (e.g., an inert gas), a vapor flux, a vacuum chamber, and/or a coating zone.

At activity 5200, a component can be inserted in the system. The component can be constructed for use in an aircraft. The component can comprise steel.

At activity 5300, a coating material can be placed in the system.

At activity 5400, the coating material can be heated to generate a vapor that can be comprised by a vapor flux.

At activity 5500, an electrical bias can be applied to the component.

At activity 5600, the component is coated. Certain exemplary embodiments cause a substantially uniform coating to be deposited on a substrate. The coating can be deposited via a coating material stream that emanates from one or more vapor sources. The coating material stream is directed toward the substrate via a carrier gas in a chamber under vacuum. The carrier gas substantially surrounds the coating material stream as the substrate is exposed to the coating material stream. The vapor sources can move relative to the substrate. In certain exemplary embodiments comprise vapor sources that move vertically and/or radially relative to the substrate. A heat source can be used to evaporate and/or sublimate the source material.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a—at least one.
activity—an action, act, step, and/or process or portion thereof.
actuator—a mechanical device constructed to move or control something.
adapter—a device used to effect operative compatibility between different parts of one or more pieces of an apparatus or system.
air—a mixture of nitrogen, oxygen, and other gases that surround the earth and form its atmosphere.
aircraft—a vehicle constructed to move while the vehicle is above ground level.
alloy—a substance comprising two or more metals.
and/or—either in conjunction with or in alternative to.
angle—a geometric figure formed by two lines that begin at a common point or by two planes that begin at a common line. The space between such lines or planes, measured in degrees.
annular—ring shaped.
apparatus—an appliance or device for a particular purpose.
apply—to coat.
associate—to join, connect together, and/or relate.
atmospheric pressure—a value of standard atmospheric pressure, equivalent to the pressure exerted by a column of mercury of approximately 29.92 inches.
automatically—acting or operating in a manner essentially independent of external influence or control. For example, an automatic light switch can turn on upon “seeing” a person in its view, without the person manually operating the light switch.
bias—a voltage or current applied to an electrical device and/or system.
can—is capable of, in at least some embodiments.
carbon nanotube—a hollow substantially cylindrical or toroidal molecule made substantially entirely of carbon.
carrier gas—a substance that acts to convey a coating material in a chamber, which substance is in a state such that the substance expands freely to fill any space available, irrespective of a quantity of the substance.
cause—to produce an effect.
ceramic—any of various hard, brittle, heat- and corrosion-resistant materials made typically of metallic elements combined with oxygen or with carbon, nitrogen, or sulfur.
chamber—a substantially enclosed space or cavity.
chromate conversion coat—a chromate layer applied to a surface via a chemical or electro-chemical process.
coat—to provide an object with a layer over a surface of the object.
coating material—a substance to be applied as a layer to a substrate surface.
coat—to apply a layer of a coating material on a substrate.
coating—a layer of a coating material applied to a substrate.
coaxial—having a common axis.
component—a part of a larger whole.
comprising—including but not limited to.
configure—to make suitable or fit for a specific use or situation.
connect—to join or fasten together.
consecutive—following one after the other in order.
constructed to—made suitable or fit for a specific use or situation.
convert—to transform, adapt, and/or change.
coupleable—capable of being joined, connected, and/or linked together.
coupling—linking in some fashion.
create—to bring into being.
crucible—a container constructed to hold a substance, which container is constructed to allow the substance to be subjected to a gasifying temperature.
define—to establish the outline, form, or structure of.
density—the degree to which a space is filled.
device—a machine, manufacture, and/or collection thereof.
deposit—to put a layer on a surface of an object.
direct—to control a path of something.
directed vapor deposition—a method via which a layer of a coating material is put on a surface of a substrate, wherein the layer is formed via condensation of an evaporated substance on the surface of the substrate, which evaporated substance is conveyed to the surface of the substrate via a carrier gas stream. The coating material and/or carrier gas steam may pass through a plasma flux, but that is not necessarily a requirement.
directionality—indicating a direction in space.
electrically conductive—constructed to convey electricity over a distance and having a resistivity of less than approximately 1 mΩ cm.
electrically non-conductive—constructed to substantially not conduct electricity and having a resistivity of greater than approximately 1 mΩ cm.
electron beam source—a system that emits a directed electron stream.
emanate—to be emitted by.
emission direction—a primary course along which a plasma source conveys a plasma flux.
enhance—increase.
evaporate—to impart energy such that a solid or liquid changes to a gaseous state.
expose—to allow contact with.
fiber—a slender filament.
filament—a fiber, wire, or tape substrate having a length that is substantially greater than its width or thickness.
gas jet nozzle—a pipe or duct that directs a gas and accelerates the flow of the gas.
generate—to produce.
heat energy—nonmechanical energy with reference to a temperature difference between a system and its surroundings or between two parts of the same system.
hot section gas turbine engine—a portion of a jet engine in which combustion takes place.
install—to connect or set in position and prepare for use.
intermediate—situated between two other things and having at least one characteristic that is distinct from the two other things.
landing gear—an aircraft subsystem that supports the weight of an aircraft or spacecraft when in contact with the land or water.
layer—a covering over a surface.
level—magnitude.
maintain—to keep in a specified state.
may—is allowed and/or permitted to, in at least some embodiments.
metal—any of a group of chemical elements, including iron, gold, copper, lead, and magnesium, that readily become cations and form ionic bonds, having relatively free valence electrons.
method—a process, procedure, and/or collection of related activities for accomplishing something.
monofilament—a single fiber filament.
move—to change position.
multiple—more than one.
net—remaining after an interaction.
non-line-of-site—portions of something that are not visible to a human via observation from a fixed point in space.
nuclear fuel cladding—a coating of a rod used as a fuel source in a nuclear reactor.
offset—substantially not aligned with.
parallel—extending substantially in a same direction, approximately equidistant at all points, and substantially not converging or diverging.
plasma—One of four main states of matter, similar to a gas, but consisting of positively charged ions with most or all of their detached electrons moving freely about.
plasma current—an electron flow applied to a plasma source
plasma flux—a flow of plasma from a plasma source.
plasma generated ions—positively charged atoms or molecules created and conveyed by a plasma source.
plasma source—a system constructed to impart energy to a coating material and thereby generate a plasma.
plurality—the state of being plural and/or more than one.
polarity—a relative direction of an electrical or magnetic field.
polymer—a compound of relatively high molecular weight derived either by the addition of many smaller molecules or by the condensation of many smaller molecules with the elimination of water, alcohol, or the like.
predetermined—established in advance.
pre-heater—a subsystem that heats something before that something is subjected to a further process.
pressure—a substantially continuous physical force exerted on or against an object by something in contact with the object.
pressure ratio—a quantitative relation between two pressures showing the number of times one pressure is when mathematically divided by the other.
probability—a quantitative representation of a likelihood of an occurrence.
provide—to furnish, supply, give, and/or make available.
pure—substantially of a single substance.
radial—moving along a radius.
receive—to get as a signal, take, acquire, and/or obtain.
relative—in connection with another thing.
repeatedly—again and again; repetitively.
set—a related plurality.
simultaneous—occurring at substantially at the same time.
stream—a flow of something.
substantially—to a great extent or degree.
sublimate—to change a solid to a gaseous state substantially without the solid passing through a liquid state.
substrate—a substance or layer upon which one or more predetermined layers are deposited.
superconductive—having substantially no electrical resistance, and having an ability to carry electric current with substantially no loss of energy.
support—to bear the weight of, especially from below.
surround—to substantially enclose on all sides.
switch—to change.
system—a collection of mechanisms, devices, machines, articles of manufacture, processes, data, and/or instructions, the collection designed to perform one or more specific functions.
thickness—a distance between opposite sides of an object.
transfer—to go from one thing to another.
uniform—having a thickness that is within approximately ten percent of being the same over a surface.
uniform access—having a substantially equal probability of being deposited in a given location as compared to any other location on a surface.
vacuum —pressure that is lower than atmospheric pressure.
vacuum pump—a system that reduces pressure in a chamber to a level that is below atmospheric pressure.
vapor source—a crucible from which gaseous stream emanates, the gaseous stream comprising a coating material to be applied as a layer to a substrate.
vertical—substantially perpendicular to the plane of the horizon.
via—by way of and/or utilizing.
weight—a value indicative of importance.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing FIG., etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing FIG., etc.) of this application, other than the claims themselves, is to be regarded as illustrative in nature, and not as restrictive, and the scope of subject matter protected by any patent that issues based on this application is defined only by the claims of that patent.

What is claimed is:

1. A system comprising:
a substrate;
a coating material stream that emanates from one or more vapor sources, said coating material stream directed toward said substrate via a carrier gas in a coating chamber under vacuum, said carrier gas substantially surrounding said coating material stream as said substrate is exposed to a coating material comprised by said coating material stream, wherein:
said coating material stream moves relative to said substrate as said coating material is deposited on said substrate; and
said coating material is deposited as a substantially uniform layer on said substrate via non-line of sight coating of at least a portion of said substrate.

2. The system of claim 1, further comprising:
a plasma source that ionizes at least a portion of said coating material or carrier gas.

3. The system of claim 1, further comprising:
a pre-heater that transfers heat energy to said substrate.

4. The system of claim 1, further comprising:
an electron beam source that supplies an electron beam that evaporates or sublimates said coating material.

5. The system of claim 1, further comprising:
a vacuum pump that creates a vacuum in said chamber.

6. The system of claim 1, further comprising:
a plurality of metal crucibles from which wires are evaporated to generate said coating material stream.

7. The system of claim 1, wherein:
a bias is applied to said substrate to enhance a coating density of said coating material on said substrate.

8. The system of claim 1, wherein:
said carrier gas is directed in said chamber via a gas jet nozzle.

9. The system of claim 1, wherein:
said carrier gas is directed in said chamber via a gas jet nozzle, said gas jet nozzle comprising at least one of an angular channel and a non-angular channel, said nozzle defined by a shape selected from the group consisting of: ring-shaped, elliptical-shaped, elongated elliptical-shaped, cross-hatched-shaped, segmented ring-shaped, segmented elliptical-shaped, and segmented elongated elliptical-shaped.

10. The system of claim 1, wherein:
said coating material comprises a metal or alloy.

11. The system of claim 1, wherein:
said coating material comprises aluminum.

12. The system of claim 1, wherein:
said coating material comprises an aluminum alloy.

13. The system of claim 1, wherein:
said substrate is an aircraft component.

14. The system of claim 1, wherein:
said substrate is an aircraft landing gear, actuator, or connector component.

15. The system of claim 1, wherein:
an internal portion of said substrate is coated via non line of sight coating.

16. A method comprising:
depositing a substantially uniform coating on a substrate, said coating deposited via a coating material stream that emanates from one or more vapor sources, said coating material stream directed toward said substrate via a carrier gas in a chamber under vacuum, said carrier gas substantially surrounding said coating material stream as said substrate is exposed to said coating material stream, wherein said substrate moves relative to said coating material stream.

17. The method of claim 16, wherein:
said substrate moves vertically relative to the coating material stream

18. The method of claim 16, wherein,
multiple vapor sources, offset vertically and directionally are utilized simultaneously or consecutively.

19. The method of claim 16, further comprising:
moving said substrate through an intermediate chamber, said intermediate chamber maintained at a vacuum level between atmospheric pressure and a vacuum level of a coating chamber, wherein said substrate enters said intermediate chamber prior to entering said coating chamber.

20. The method of claim 16, further comprising:
applying a chromate conversion coat to said substrate.

21. A method comprising:
depositing a substantially uniform coating on a substrate, said coating deposited via a coating material stream that emanates from one or more vapor sources, said coating material stream directed toward said substrate via a carrier gas in a chamber under vacuum, said carrier gas substantially surrounding said coating material stream as said substrate is exposed to said coating material stream, wherein said vapor sources move relative to the substrate.

22. The method of claim 21, wherein:
said vapor sources moves vertically relative to the substrate

23. The method of claim 21, wherein:
said vapor sources moves radially relative to the substrate

24. The method of claim 21, wherein:
a heat source is used to evaporate or sublimate a source material comprised by said vapor sources.
